(19) United States
(12) Patent Application Publication
(10) Pub. No.: US 2025/0331326 A1
(43) Pub. Date: Oct. 23, 2025

(54) PHOTODETECTION DEVICE AND ELECTRONIC DEVICE

(71) Applicant: SONY SEMICONDUCTOR SOLUTIONS CORPORATION, Kanagawa (JP)

(72) Inventors: Tomoki HIRANO, Kanagawa (JP); Suguru SAITO

(73) Assignee: SONY SEMICONDUCTOR SOLUTIONS CORPORATION, Kanagawa (JP)

(21) Appl. No.: 18/866,458

(22) PCT Filed: Apr. 25, 2023
(86) PCT No.: PCT/JP2023/016303

§ 371 Date: Nov. 15, 2024

(30) Foreign Application Priority Data
Jun. 2, 2022 (JP) 2022-090130

(51) Int. Cl. H10F 39/00; H10F 39/18

(52) U.S. Cl. CPC H10F 39/8063; H10F 39/182

(57) ABSTRACT

Provided is a photodetection device capable of achieving both absorption suppression in a light condensing section and negative bias pinning by a conductor film. The photodetection device includes a semiconductor layer, a pixel separation region, and an on-chip lens. The semiconductor layer includes a plurality of pixels arranged in an array, the pixels capable of generating an electrical signal according to light incident from outside. The pixel separation region is formed in the semiconductor layer and separates adjacent pixels from each other. The on-chip lens is arranged on a light incident surface side of the semiconductor layer, is formed for each pixel group including two or more pixels, and condenses light from the outside on the pixel group. The pixel separation region includes a light condensing section of light by the on-chip lens. The light condensing section includes a first material extending in a thickness direction of the semiconductor layer, and sections other than the light condensing section include a second material extending in the thickness direction of the semiconductor layer and different from the first material.

### TECHNICAL FIELD

The technology according to an embodiment of the present disclosure (present technology) relates to a photodetection device and an electronic device including the photodetection device.

### BACKGROUND ART

Conventionally, a solid-state imaging element such as a charge coupled device (CCD) and a complementary metal oxide semiconductor (CMOS) image sensor is used, for example, as a photodetection device in an electronic device having an imaging function such as a digital still camera and a digital video camera. The photodetection device includes pixels in which a photodiode (photoelectric conversion element) that performs photoelectric conversion and a transistor are combined, and an image is formed on the basis of pixel signals output from a plurality of pixels arranged two-dimensionally.

Furthermore, in recent years, an image sensor having a structure in which one on-chip lens is formed on two or more pixels has also been proposed. In this type of image sensor, a part of a plurality of pixels under the on-chip lens is used to detect a phase, thereby improving an autofocus (AF) speed. Furthermore, phase information is generated on the basis of a pixel signal obtained by each pixel, and ranging is performed on the basis of the phase information.

Note that, in a case where strong light is incident on a pixel, a phenomenon referred to color mixing might occur in which charges accumulated in a photodiode of the pixel are saturated and overflow, and leak to an adjacent pixel. Therefore, a solid-state imaging device provided with a pixel separation region that separates pixels has been proposed (for example, Patent Document 1).

### CITATION LIST

### Patent Document

Patent Document 1: Japanese Patent Application Laid-Open No. 2021-27276

### SUMMARY OF THE INVENTION

### Problems to be Solved by the Invention

Note that, for the purpose of improving quantum efficiency (Qe) of each pixel, a technology has been conventionally proposed in which a conductor film (for example, a polysilicon film containing boron or an amorphous silicon film containing boron) is embedded in a pixel separation region via an insulating film, and a negative bias is applied to the conductor film in the pixel separation region to enhance pinning on a side wall of the pixel separation region.

However, in a structure in which one on-chip lens is formed on two or more pixels, incident light is condensed on the pixel separation region via the on-chip lens, and the incident light is absorbed by the light condensing section, so that the quantum efficiency is deteriorated.

The present disclosure has been achieved in view of such circumstances, and an object thereof is to provide a photodetection device capable of achieving both absorption suppression in a light condensing section and negative bias pinning by a conductor film, and an electronic device.

### Solutions to Problems

An aspect of the present disclosure is a photodetection device including a semiconductor layer in which a plurality of pixels capable of generating an electric signal according to light incident from outside is arranged in a matrix, a pixel separation region that is formed in the semiconductor layer and separates adjacent pixels from each other, and an on-chip lens that is arranged on a light incident surface side of the semiconductor layer, is formed for each pixel group including two or more pixels, and condenses the light from the outside to the pixel group, in which the pixel separation region includes a light condensing section of the light by the on-chip lens, and the light condensing section includes a first material extending in a thickness direction of the semiconductor layer, and sections other than the light condensing section have a second material extending in the thickness direction of the semiconductor layer, the material different from the first material.

Another aspect of the present disclosure is an electronic device including a photodetection device including a semiconductor layer in which a plurality of pixels capable of generating an electric signal according to light incident from outside is arranged in a matrix, a pixel separation region that is formed in the semiconductor layer and separates adjacent pixels from each other, and an on-chip lens that is arranged on a light incident surface side of the semiconductor layer, is formed for each pixel group including two or more pixels, and condenses the light from the outside to the pixel group, in which the pixel separation region includes a light condensing section of the light by the on-chip lens, and the light condensing section includes a first material extending in a thickness direction of the semiconductor layer, and sections other than the light condensing section have a second material extending in the thickness direction of the semiconductor layer, the material different from the first material.

### BRIEF DESCRIPTION OF DRAWINGS

FIG. 1 is a block diagram depicting an example of a schematic configuration of a photodetection device according to a first embodiment of the present disclosure.

FIG. 2 is a partial longitudinal cross-sectional view depicting an example of a semiconductor structure of the photodetection device according to the first embodiment of the present disclosure.

FIG. 3 is a plan view depicting a configuration example of a pixel layout according to a comparative example and an arrangement example of an on-chip lens with respect to the pixel layout.

FIG. 4 is a partial longitudinal cross-sectional view depicting an example of a semiconductor structure of a photodetection device according to the comparative example.

FIG. 5 is a plan view depicting an arrangement example of an on-chip lens with respect to a pixel layout according to the first embodiment of the present disclosure.

FIG. 6A is a partial longitudinal cross-sectional view depicting an example of the semiconductor structure of the photodetection device taken along line A-A′ in FIG. 5.

FIG. 6B is a partial longitudinal cross-sectional view depicting an example of the semiconductor structure of the photodetection device taken along line B-B′ in FIG. 5.

FIG. 7 is a plan view depicting a configuration example of a pixel layout of a photodetection device according to a second embodiment of the present disclosure and an arrangement example of an on-chip lens with respect to the pixel layout.

FIG. 8A is a plan view depicting an arrangement example of an on-chip lens with respect to a pixel layout of a photodetection device according to a third embodiment of the present disclosure.

FIG. 8B is a plan view depicting an arrangement example of an on-chip lens with respect to a pixel layout of a photodetection device according to a first variation of the third embodiment of the present disclosure.

FIG. 8C is a plan view depicting an arrangement example of an on-chip lens with respect to a pixel layout of a photodetection device according to a second variation of the third embodiment of the present disclosure.

FIG. 9 is a plan view depicting an arrangement example of an on-chip lens with respect to a pixel layout of a photodetection device according to a fourth embodiment of the present disclosure.

FIG. 10A is a plan view depicting a configuration example of a pixel layout of a photodetection device according to a fifth embodiment of the present disclosure.

FIG. 10B is a partial longitudinal cross-sectional view depicting an example of a semiconductor structure of the photodetection device according to the fifth embodiment of the present disclosure.

FIG. 11A is a cross-sectional view (part 1) depicting a process procedure of a method for manufacturing a photodetection device according to a sixth embodiment of the present disclosure.

FIG. 11B is a cross-sectional view (part 2) depicting a process procedure of a method for manufacturing a photodetection device according to a sixth embodiment of the present disclosure.

FIG. 11C is a cross-sectional view (part 3) depicting a process procedure of a method for manufacturing a photodetection device according to a sixth embodiment of the present disclosure.

FIG. 11D is a cross-sectional view (part 4) depicting a process procedure of a method for manufacturing a photodetection device according to a sixth embodiment of the present disclosure.

FIG. 11E is a cross-sectional view (part 5) depicting a process procedure of a method for manufacturing a photodetection device according to a sixth embodiment of the present disclosure.

FIG. 11F is a cross-sectional view (part 6) depicting a process procedure of a method for manufacturing a photodetection device according to a sixth embodiment of the present disclosure.

FIG. 11G is a cross-sectional view (part 7) depicting a process procedure of a method for manufacturing a photodetection device according to a sixth embodiment of the present disclosure.

FIG. 11H is a cross-sectional view (part 8) depicting a process procedure of a method for manufacturing a photodetection device according to a sixth embodiment of the present disclosure.

FIG. 12A is a cross-sectional view (part 1) depicting a process procedure of the method for manufacturing the photodetection device in a case where doping of p-type impurities is performed according to a seventh embodiment of the present disclosure.

FIG. 12B is a cross-sectional view (part 2) depicting a process procedure of the method for manufacturing the photodetection device in a case where doping of p-type impurities is performed according to a seventh embodiment of the present disclosure.

FIG. 12C is a cross-sectional view (part 3) depicting a process procedure of the method for manufacturing the photodetection device in a case where doping of p-type impurities is performed according to a seventh embodiment of the present disclosure.

FIG. 12D is a cross-sectional view (part 4) depicting a process procedure of the method for manufacturing the photodetection device in a case where doping of p-type impurities is performed according to a seventh embodiment of the present disclosure.

FIG. 12E is a cross-sectional view (part 5) depicting a process procedure of the method for manufacturing the photodetection device in a case where doping of p-type impurities is performed according to a seventh embodiment of the present disclosure.

FIG. 12F is a cross-sectional view (part 6) depicting a process procedure of the method for manufacturing the photodetection device in a case where doping of p-type impurities is performed according to a seventh embodiment of the present disclosure.

FIG. 13A is a cross-sectional view (part 1) depicting a process procedure in a case where a STI is formed according to an eighth embodiment of the present disclosure.

FIG. 13B is a cross-sectional view (part 2) depicting a process procedure in a case where a STI is formed according to an eighth embodiment of the present disclosure.

FIG. 13C is a cross-sectional view (part 3) depicting a process procedure in a case where a STI is formed according to an eighth embodiment of the present disclosure.

FIG. 13D is a cross-sectional view (part 4) depicting a process procedure in a case where a STI is formed according to an eighth embodiment of the present disclosure.

FIG. 13E is a cross-sectional view (part 5) depicting a process procedure in a case where a STI is formed according to an eighth embodiment of the present disclosure.

FIG. 13F is a cross-sectional view (part 6) depicting a process procedure in a case where a STI is formed according to an eighth embodiment of the present disclosure.

FIG. 14A is a cross-sectional view (part 1) depicting a manufacturing process procedure in a case where alkali etching is not performed in a back surface process in a ninth embodiment of the present disclosure.

FIG. 14B is a cross-sectional view (part 2) depicting a manufacturing process procedure in a case where alkali etching is not performed in a back surface process in a ninth embodiment of the present disclosure.

FIG. 14C is a cross-sectional view (part 3) depicting a manufacturing process procedure in a case where alkali etching is not performed in a back surface process in a ninth embodiment of the present disclosure.

FIG. 14D is a cross-sectional view (part 4) depicting a manufacturing process procedure in a case where alkali etching is not performed in a back surface process in a ninth embodiment of the present disclosure.

FIG. 14E is a cross-sectional view (part 5) depicting a manufacturing process procedure in a case where alkali etching is not performed in a back surface process in a ninth embodiment of the present disclosure.

FIG. 15 is a block diagram depicting a configuration example of an imaging device as an electronic device to which the present technology is applied.

FIG. 16 is a block diagram depicting an example of schematic configuration of a vehicle control system as an example of a mobile body control system to which the technology according to an embodiment of the present disclosure can be applied.

FIG. 17 is a diagram depicting an example of an installation position of an imaging section depicted in FIG. 16.

### MODE FOR CARRYING OUT THE INVENTION

Hereinafter, embodiments of the present disclosure will be described with reference to the drawings. In the illustration of the drawings referred to in the following description, the same or similar parts are denoted by the same or similar reference signs and redundant description is omitted. However, it should be noted that the drawings are schematic, and a relationship between a thickness and a planar dimension, a ratio of thicknesses of each device and each member, and the like are different from actual ones. Therefore, specific thicknesses and dimensions should be determined in consideration of the following description.

Furthermore, it goes without saying that dimensional relationships and ratios are partly different between the drawings.

In the present specification, a “first conductivity type” means one of a p-type or an n-type, and a “second conductivity type” means one of the p-type or the n-type different from the “first conductivity type”. Furthermore, “n” or “p” to which “+” or “−” is added means a semiconductor region having a relatively higher or lower impurity density than that of a semiconductor region to which “+” or “−” is not added. However, even in the semiconductor regions to which the same “n” and “n” are added, it does not mean that the impurity densities of the semiconductor regions are exactly the same.

Furthermore, definition of directions such as upward and downward directions in the following description is merely the definition for convenience of description, and does not limit the technical idea of the present disclosure. For example, it goes without saying that if a target is observed while being rotated by 90°, the upward and downward directions are converted into rightward and leftward directions, and if the target is observed while being rotated by 180°, the upward and downward directions are inverted.

Note that, the effects described in the present specification are merely examples and are not limited, and there may be other effects.

### First Embodiment

### (Overall Configuration of Photodetection Device)

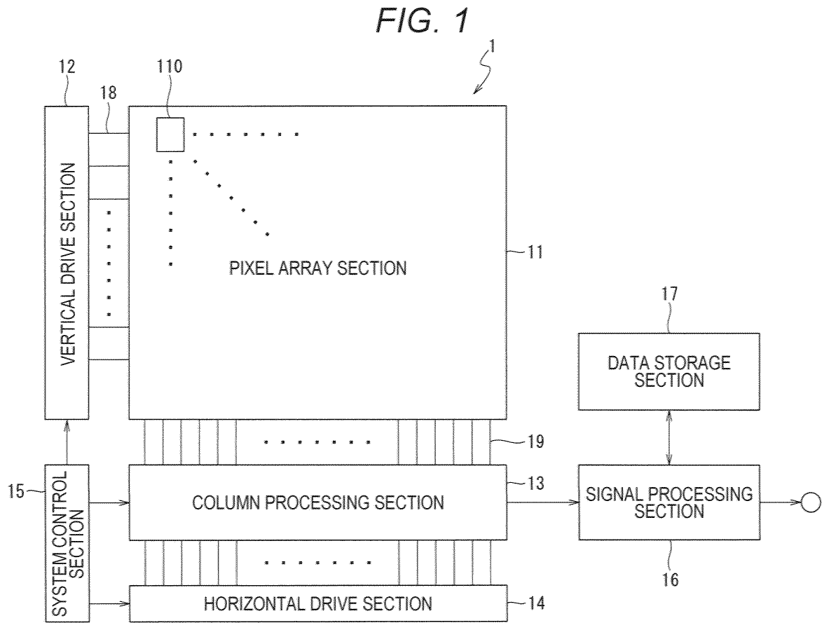

FIG. 1 is a block diagram depicting an example of a schematic configuration of a photodetection device according to a first embodiment of the present disclosure. A photodetection device 1 is a semiconductor device that converts, using a photoelectric conversion element such as a photodiode forming each pixel, a charge amount corresponding to intensity of light formed as an image on the pixel into an electric signal, and outputs the same as image data, and is configured as, for example, a CMOS image sensor. The photodetection device 1 can be integrally configured as, for example, a system on a chip (SoC) such as a CMOS LSI, but for example, some components described below may be configured as separate LSIs.

As depicted in the drawing, the photodetection device 1 includes components such as a pixel array section 11, a vertical drive section 12, a column processing section 13, a horizontal drive section 14, a system control section 15, a signal processing section 16, and a data storage section 17, for example.

The pixel array section 11 includes a photoelectric conversion element group such as photodiodes forming pixels 110 arrayed in a horizontal direction (row direction) and a vertical direction (column direction). The pixel array section 11 converts a charge amount corresponding to intensity of incident light formed as an image on each pixel 110 into an electric signal and outputs the same as a pixel signal. The pixel array section 11 can include, for example, effective pixels arranged in a region capable of receiving actual light and dummy pixels arranged outside the region and shielded by metal and the like. Note that, an optical element such as a micro-on-chip lens that condenses incident light or a color filter is formed on each pixel 110 of the pixel array section 11 (not depicted).

The vertical drive section 12 includes a shift register, an address decoder, and the like. The vertical drive section 12 supplies a drive signal and the like to each pixel 110 via a plurality of pixel drive lines 18, thereby driving each pixel 110 of the pixel array section 11, for example, simultaneously or row by row.

The column processing section 13 reads the pixel signal from each pixel via a vertical signal line (VSL) 19 for each pixel column of the pixel array section 11, and performs noise removal processing, correlated double sampling (CDS) processing, analog-to-digital (A/D) conversion processing, and the like. The pixel signal processed by the column processing section 13 is output to the signal processing section 16.

The horizontal drive section 14 includes a shift register, an address decoder, and the like. The horizontal drive section 14 sequentially selects the pixels 110 corresponding to the pixel columns of the column processing section 13. By selective scanning by the horizontal drive section 14, the pixel signals subjected to the signal processing for each pixel 110 in the column processing section 13 are sequentially output to the signal processing section 16.

The system control section 15 includes a timing generator that generates various timing signals and the like. The system control section 15 performs drive control of the vertical drive section 12, the column processing section 13, and the horizontal drive section 14 on the basis of, for example, a timing signal generated by a timing generator not depicted.

The signal processing section 16 performs signal processing such as arithmetic processing on the pixel signal supplied from the column processing section 13 while temporarily storing data in the data storage section 17 as necessary, and outputs an image signal based on each pixel signal. Furthermore, the signal processing section 16 performs the signal processing according to a flag output from the column processing section 13.

Note that, the photodetection device 1 to which the present technology is applied is not limited to the configuration as described above. For example, the photodetection device 1 may be configured in such a manner that the data storage section 17 is arranged at a subsequent stage of the column processing section 13, and the pixel signal output from the column processing section 13 is supplied to the signal processing section 16 via the data storage section 17. Alternatively, the photodetection device 1 may be configured in such a manner that the column processing section 13, the data storage section 17, and the signal processing section 16 connected in cascade process the respective pixel signals in parallel.

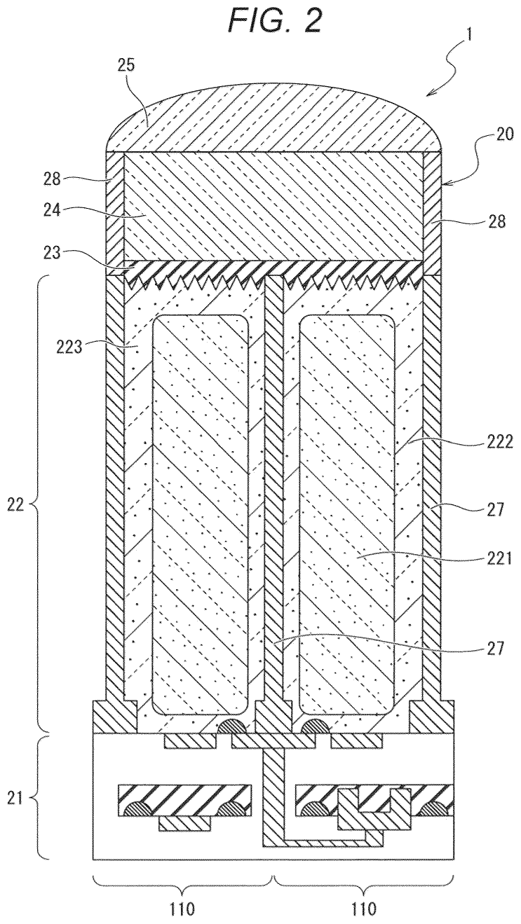

FIG. 2 is a partial longitudinal cross-sectional view depicting an example of a semiconductor structure of the photodetection device 1 according to the first embodiment of the present disclosure. As depicted in the drawing, a semiconductor structure 20 schematically includes, for example, a wiring layer 21, a semiconductor layer 22, a planarizing film 23, a color filter 24, and an on-chip lens 25. Such semiconductor structure 20 can be configured, for example, by integrally joining a first silicon substrate including the wiring layer 21 and various logic circuits (not depicted), and a second silicon substrate including the semiconductor layer 22.

The on-chip lens 25 is an optical lens for efficiently condensing light incident on the photodetection device 1 from outside and forming an image on a plurality of corresponding pixels 110 of the semiconductor layer 22. In this example, one on-chip lens 25 is arranged for every four pixels 110 in which the pixels 110 are arranged two by two in the horizontal direction (column direction) and the vertical direction (row direction) in plan view. Note that, the on-chip lens 25 includes, for example, silicon oxide, silicon nitride, silicon oxynitride, organic SOG, a polyimide resin, a fluorine resin or the like.

The color filter 24 is an optical filter that selectively transmits light of a predetermined wavelength out of the light condensed by the on-chip lens 25. In this example, four color filters 24 that selectively transmit wavelengths of red light, green light, blue light, and near-infrared light are used, but there is no limitation. The color filter 24 corresponding to any color (wavelength) is arranged in each pixel 110.

The semiconductor layer 22 is a functional layer in which a pixel circuit group including a photoelectric conversion section 221 such as a photodiode forming each pixel 110 and various electronic elements such as transistors are formed. Each photoelectric conversion section 221 of the semiconductor layer 22 generates a charge amount corresponding to intensity of light incident via the on-chip lens 25 and the color filter 24, converts the same into the electric signal, and outputs the same as the pixel signal. The photoelectric conversion section 221 is an n-type region. Note that, a part of the light (for example, near-infrared light and the like) incident on an incident surface of the semiconductor layer 22 can pass a surface (that is, a front surface) opposite to the incident surface (that is, a back surface). The semiconductor layer 22 is manufactured on a silicon substrate by a semiconductor manufacturing process. The photoelectric conversion section 221 and the various electronic elements are electrically connected to a predetermined metal wire in the wiring layer 21.

Furthermore, in the semiconductor layer 22, a pixel separation section 27 that separates the pixels 110 from each other can be formed. The pixel separation section 27 has, for example, a trench structure formed by etching processing. The pixel separation section 27 prevents light incident on the pixel 110 from entering the adjacent pixel 110. A p-type region 222 is formed between the photoelectric conversion section 221 and the pixel separation section 27. Therefore, a silicon interface is pinned by the p-type region 222, so that generation of a dark current is suppressed.

The wiring layer 21 is a layer in which a metal wiring pattern for transmitting power and various drive signals to each pixel 110 in the semiconductor layer 22 and transmitting the pixel signal read from each pixel 110 is formed. The wiring layer 21 can typically include a plurality of layers of metal wiring pattern stacked with an interlayer insulating film interposed therebetween. Furthermore, the stacked metal wiring patterns are electrically connected by, for example, vias, as necessary. The wiring layer 21 includes, for example, metal such as aluminum (Al) and copper (Cu). In contrast, the interlayer insulating film includes, for example, silicon oxide and the like.

Light shielding walls 28 are provided on both ends of the color filter 24 and the on-chip lens 25. The light shielding walls 28 are formed into a lattice shape so as to open the photoelectric conversion section 221. That is, the light shielding wall 28 is formed at a position corresponding to the pixel separation section 27. The light shielding wall 28 is formed at a position overlapping the pixel separation section 27 in plan view. A material that shields light may be used as the material forming the light shielding wall 28, and for example, tungsten (W), aluminum (Al), or copper (Cu) can be used. Alternatively, silicon oxide (SiO) as a low refractive material and air (Air) can be used.

The planarizing film 23 is formed between the semiconductor layer 22 and the color filter 24, and planarizes a back surface side surface of the semiconductor layer 22. An antireflection section having an uneven shape is sometimes provided on the back surface side of the semiconductor layer 22.

### Comparative Example of Embodiment

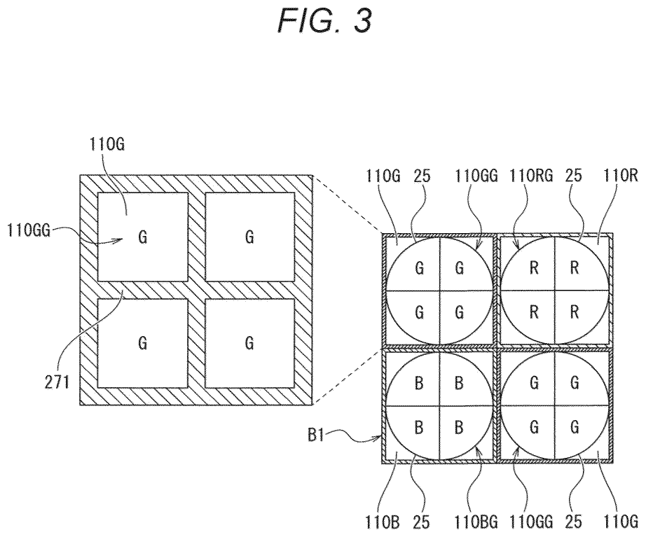

FIG. 3 is a plan view depicting a configuration example of a pixel layout according to a comparative example and an arrangement example of the on-chip lens 25 with respect to the pixel layout. In FIG. 3, a pixel 110 denoted by a reference sign G is a green pixel 110G covered with a G filter that transmits green light out of the color filters 24. A pixel 110 denoted by a reference sign R is a red pixel 110R covered with an R filter that transmits red light out of the color filters 24. A pixel 110 denoted by a reference sign B is a blue pixel 110B covered with a B filter that transmits blue light out of the color filters 24.

As depicted in FIG. 3, a photodetection device B1 includes, for example, a green pixel group 110GG, a red pixel group 110RG, and a blue pixel group 110BG. The green pixel group 110GG includes four pixels in which green pixels 110G are arranged two by two in a horizontal direction and a vertical direction in plan view. The red pixel group 110RG includes four pixels in which red pixels 110R are arranged two by two in a horizontal direction and a vertical direction in plan view. The blue pixel group 110BG includes four pixels in which blue pixels 110B are arranged two by two in a horizontal direction and a vertical direction in plan view.

The green pixel group 110GG, the red pixel group 110RG, and the blue pixel group 110BG form a unit layout. For example, a pair of green pixel groups 110GG are arranged on a diagonal line, and the red pixel group 110RG and the blue pixel group 110BG are arranged on a diagonal line to form the unit layout. The pixel layout of the photodetection device B1 has a configuration in which the unit layout is repeatedly arranged in the horizontal direction and the vertical direction in plan view. Therefore, in the green pixel group 110GG, the red pixel group 110RG, and the blue pixel group 110BG, pixel groups of different colors are adjacent to each other in the horizontal direction and the vertical direction in plan view.

As depicted in FIG. 3, one on-chip lens 25 is arranged for every four pixels in which the pixels are arranged two by two in the horizontal direction and the vertical direction in plan view. For example, one on-chip lens 25 is arranged in one green pixel group 110GG. One on-chip lens 25 is arranged in one red pixel group 110RG. One on-chip lens 25 is arranged in one blue pixel group 110BG.

As depicted in FIG. 3, in the configuration example of the pixel layout, pixels of the same color and pixels of different colors are respectively separated by the pixel separation section 27 having a trench separation structure. For example, the pixel separation section 27 includes a same-color pixel separation section 271 for separating the adjacent pixels 110 of the same color and a different-color pixel separation section 272 for separating the adjacent pixels 110 of different colors. One green pixel 110G and the other green pixel 110G adjacent to each other, one red pixel 110R and the other red pixel 110R adjacent to each other, and one blue pixel 110B and the other blue pixel 110B adjacent to each other are respectively separated by the same-color pixel separation section 271. Furthermore, the green pixel 110G and the red pixel 110R adjacent to each other and the green pixel 110G and the blue pixel 110B adjacent to each other are respectively separated from each other by the different-color pixel separation section 272. Note that, being adjacent means being adjacent in the horizontal direction or the vertical direction in plan view.

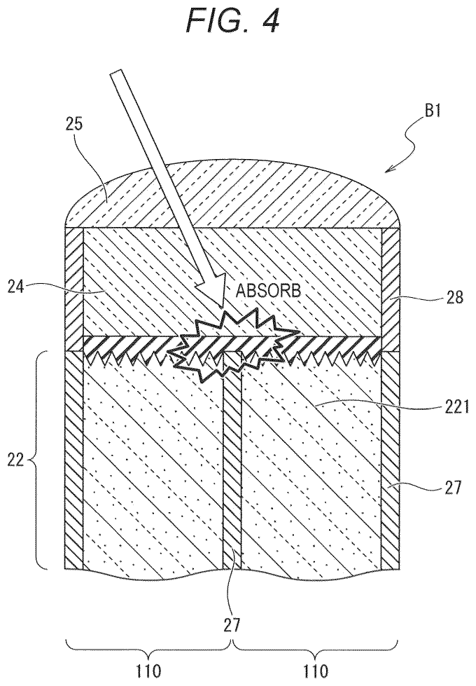

FIG. 4 is a partial longitudinal cross-sectional view depicting an example of a semiconductor structure of the photodetection device B1 according to the comparative example. In FIG. 4, the same portions as those in FIG. 2 described above are denoted by the same reference signs, and detailed description thereof is omitted.

In the photodetection device B1, when a polysilicon film containing boron, an amorphous silicon film containing boron, and the like is embedded in the pixel separation section 27 for negative bias pinning, incident light is absorbed by a light condensing section by the on-chip lens 25, and thus quantum efficiency (Qe) as a pixel characteristic is deteriorated.

### Solving Means of First Embodiment

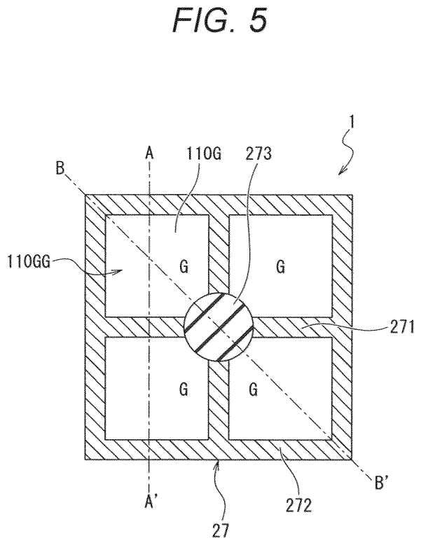

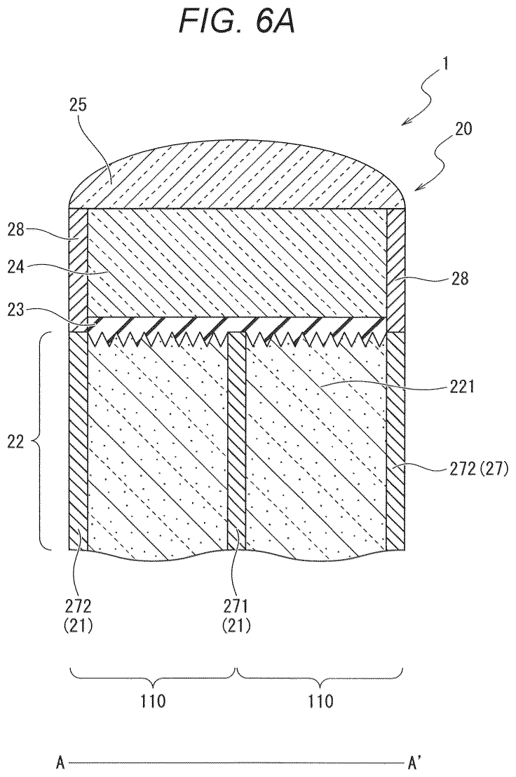

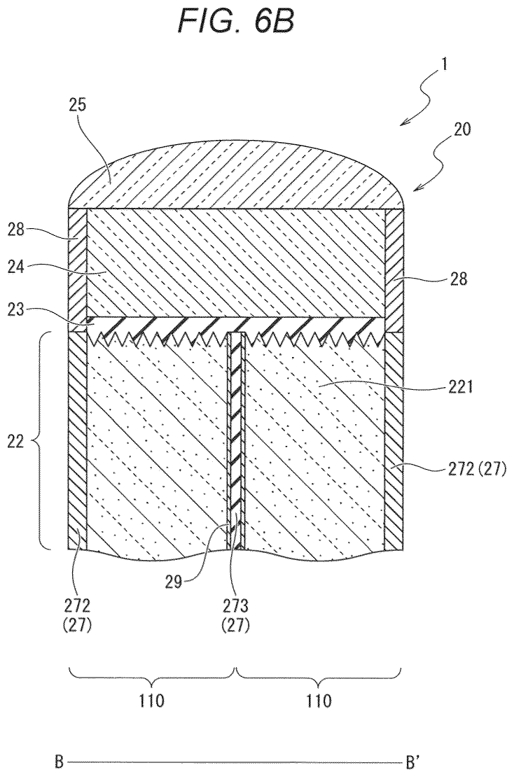

To solve the above-described problem, in the first embodiment of the present disclosure, as depicted in FIG. 5, the pixel separation section 27 includes a light condensing section 273 of light by the on-chip lens 25. FIG. 6A is a partial longitudinal cross-sectional view depicting an example of the semiconductor structure 20 of the photodetection device 1 taken along line A-A′ in FIG. 5. FIG. 6B is a partial longitudinal cross-sectional view depicting an example of the semiconductor structure 20 of the photodetection device 1 taken along line B-B′ in FIG. 5. Line A-A′ is an imaginary line passing through the different-color pixel separation section 272, the green pixel 110G, and the same-color pixel separation section 271 in plan view. Line B-B′ is an imaginary line passing through the different-color pixel separation section 272, the green pixel 110G, and the light condensing section 273 in plan view.

As depicted in FIG. 6B, at least one of silicon oxide, titanium oxide, air, or a transparent electrode is embedded in the light condensing section 273 so as to extend in a thickness direction of the semiconductor layer 22. As depicted in FIG. 6A, an amorphous silicon film containing boron with a high light absorption rate is embedded in the same-color pixel separation section 271 and the different-color pixel separation section 272 so as to extend in the thickness direction of the semiconductor layer 22.

Moreover, a fixed charge film 29 that generates a negative fixed charge is formed on an inner wall surface of the light condensing section 273. As the fixed charge film 29, it is preferable to use a material that can enhance pinning by generating a fixed charge by being deposited on a substrate such as silicon, and a high refractive index material film or a high dielectric film having a negative charge can be used.

As a specific material of the fixed charge film 29, for example, an oxide or nitride containing at least any one of elements out of hafnium (Hf), aluminum (Al), zirconium (Zr), tantalum (Ta), or titanium (Ti) can be applied.

### Effects by First Embodiment

As described above, according to the first embodiment, in the pixel separation section 27, by embedding a material having a high reflectance in the light condensing section 273 and embedding a conductor for enhancing pinning, for example, an amorphous silicon film containing boron in the same-color pixel separation section 271 and the different-color pixel separation section 272, both absorption suppression in the light condensing section 273 and negative bias pinning by the amorphous silicon film containing boron can be achieved.

Furthermore, according to the first embodiment, by using at least one of silicon oxide, titanium oxide, air, or a transparent electrode as the material to be embedded in the light condensing section 273, quantum efficiency (Qe) can be improved by high reflection in a case of silicon oxide, color mixing can be suppressed because scattering of light can be suppressed as compared with silicon oxide in a case of titanium oxide and air, and a negative bias can be applied while light absorption is suppressed in a case of the transparent electrode.

Moreover, according to the first embodiment, by forming the fixed charge film 29 that generates the negative fixed charge on the inner wall surface of the light condensing section 273, the dark current generated at an interface of the semiconductor layer 22 including the photoelectric conversion section 221 can be suppressed by the fixed charge film 29.

Note that, in the first embodiment, a p-type region may be formed on a side wall of the light condensing section 273. In this manner, absorption can be suppressed and pinning can be enhanced in the light condensing section 273.

For example, in a case where a through-pixel separation structure is applied to a fine pixel of 0.7 μm or less, it is desirable to set a thickness of the silicon substrate to 3.7 μm or less in order to stably form a trench, that is, the pixel separation section 27, and to 2.8 μm or more in order to secure a saturation charge amount; however, since the trench is stably formed when the present invention is applied, it is also possible to secure the saturation charge amount while making the silicon substrate thicker.

### Second Embodiment

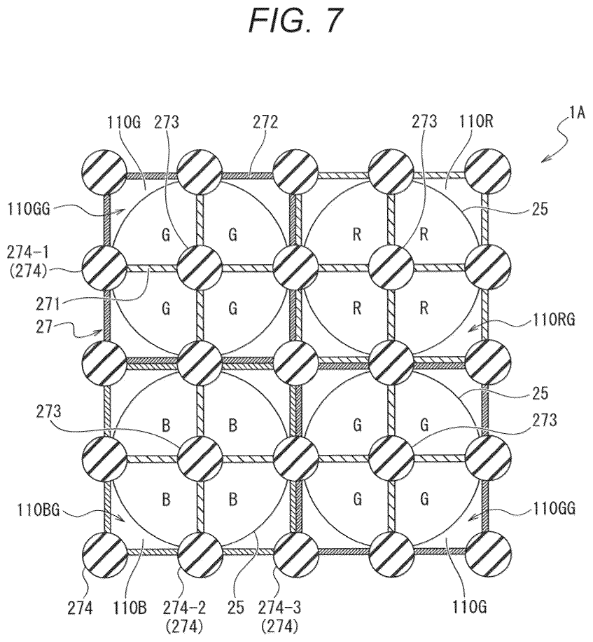

FIG. 7 is a plan view depicting a configuration example of a pixel layout of a photodetection device 1A according to a second embodiment of the present disclosure and an arrangement example of an on-chip lens 25 with respect to the pixel layout. In FIG. 7, the same portions as those in FIG. 3 described above are denoted by the same reference signs, and detailed description thereof is omitted.

In the second embodiment of the present disclosure, in a pixel separation section 27, an intersection 274-1 (274) between a same-color pixel separation section 271 extending in a horizontal direction (column direction) and a different-color pixel separation section 272 extending in a vertical direction (row direction), an intersection 274-2 (274) between the same-color pixel separation section 271 extending in the vertical direction and the different-color pixel separation section 272 extending in the horizontal direction, and an intersection 274-3 (274) between the different-color pixel separation section 272 extending in the horizontal direction and the different-color pixel separation section 272 extending in the vertical direction are provided.

At least one of silicon oxide, titanium oxide, air, or a transparent electrode is embedded in the intersection 274 so as to extend in a thickness direction of the semiconductor layer 22.

### Effects by Second Embodiment

As described above, according to the second embodiment, by embedding at least one of silicon oxide, titanium oxide, air, or a transparent electrode in the intersection 274 in addition to a light condensing section 273, it is possible to further improve light absorption suppression.

Note that, in the second embodiment, a fixed charge film that generates a negative fixed charge may be formed on an inner wall surface of the intersection 274, or a p-type region may be formed on a side wall of the intersection 274.

### Third Embodiment

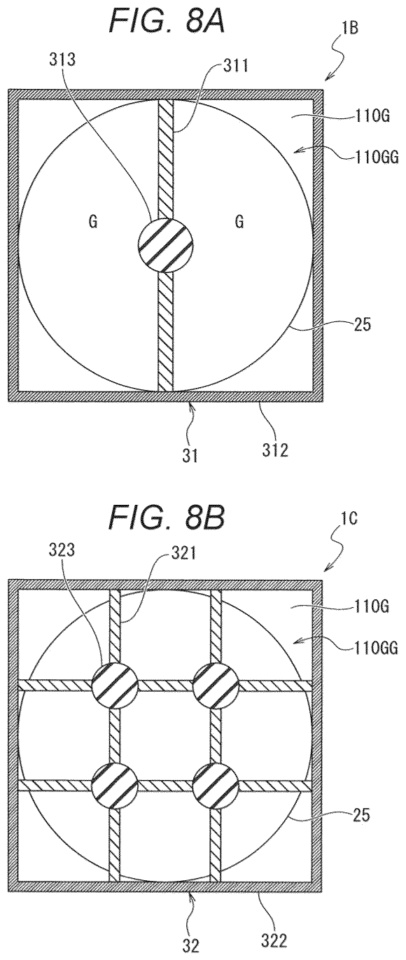

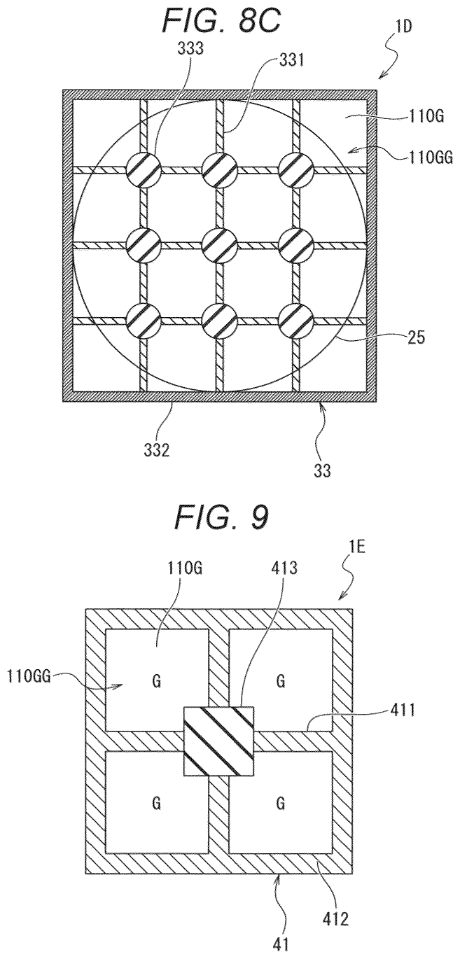

FIG. 8A is a plan view depicting an arrangement example of an on-chip lens 25 with respect to a pixel layout of a photodetection device 1B according to a third embodiment of the present disclosure. In FIG. 8A, the same portions as those in FIG. 3 described above are denoted by the same reference signs, and detailed description thereof is omitted.

As depicted in FIG. 8A, the photodetection device 1B includes, for example, a green pixel group 110GG. In the green pixel group 110GG, two green pixels 110G are arranged in a horizontal direction in plan view.

A pixel separation section 31 includes a same-color pixel separation section 311 for separating adjacent pixels 110 of the same color and a different-color pixel separation section 312 for separating adjacent pixels 110 of different colors. Furthermore, the pixel separation section 31 includes a light condensing section 313 of light by the on-chip lens 25.

At least one of silicon oxide, titanium oxide, air, or a transparent electrode is embedded in the light condensing section 313 so as to extend in a thickness direction of the semiconductor layer 22. An amorphous silicon film containing boron with a high light absorption rate is embedded in the same-color pixel separation section 311 and the different-color pixel separation section 312 so as to extend in the thickness direction of the semiconductor layer 22.

### Effects by Third Embodiment

As described above, according to the third embodiment, the effects similar to those of the first embodiment described above can be obtained, and since the two green pixels 110G are arranged in the horizontal direction (column direction), it is possible to obtain phase difference detection information in the horizontal direction.

Note that, in the third embodiment, a fixed charge film that generates a negative fixed charge may be formed on an inner wall surface of the light condensing section 313, or a p-type region may be formed on a side wall of the light condensing section 313.

### First Variation of Third Embodiment

FIG. 8B is a plan view depicting an arrangement example of an on-chip lens 25 with respect to a pixel layout of a photodetection device 1C according to a first variation of the third embodiment of the present disclosure. In FIG. 8B, the same portions as those in FIG. 3 described above are denoted by the same reference signs, and detailed description thereof is omitted.

As depicted in FIG. 8B, the photodetection device 1C includes, for example, a green pixel group 110GG. The green pixel group 110GG includes nine pixels in which green pixels 110G are arranged three by three in a horizontal direction and a vertical direction in plan view.

As depicted in FIG. 8B, one on-chip lens 25 is arranged for every nine pixels in which the pixels are arranged three by three in the horizontal direction and the vertical direction in plan view. For example, one on-chip lens 25 is arranged in one green pixel group 110GG.

A pixel separation section 32 includes a same-color pixel separation section 321 for separating adjacent pixels 110 of the same color and a different-color pixel separation section 322 for separating adjacent pixels 110 of different colors. Furthermore, the pixel separation section 32 is provided with an intersection 323 between the same-color pixel separation section 321 extending in the horizontal direction (column direction) and the same-color pixel separation section 321 extending in the vertical direction (row direction).

At least one of silicon oxide, titanium oxide, air, or a transparent electrode is embedded in the intersection 323 so as to extend in a thickness direction of a semiconductor layer 22. An amorphous silicon film containing boron with a high light absorption rate is embedded in the same-color pixel separation section 321 and the different-color pixel separation section 322 so as to extend in the thickness direction of the semiconductor layer 22.

### Effects by First Variation of Third Embodiment

As described above, according to the first variation of the third embodiment, the effects similar to those of the first embodiment described above can be obtained, and since three green pixels 110G are arranged in the horizontal direction (column direction) and the vertical direction (row direction), it is possible to obtain phase difference detection information in both the horizontal direction and the vertical direction.

Note that, in the first variation of the third embodiment, a fixed charge film that generates a negative fixed charge may be formed on an inner wall surface of the intersection 323, or a p-type region may be formed on a side wall of the intersection 323.

### Second Variation of Third Embodiment

FIG. 8C is a plan view depicting an arrangement example of an on-chip lens 25 with respect to a pixel layout of a photodetection device 1D according to a second variation of the third embodiment of the present disclosure. In FIG. 8C, the same portions as those in FIG. 3 described above are denoted by the same reference signs, and detailed description thereof is omitted.

As depicted in FIG. 8C, the photodetection device 1D includes, for example, a green pixel group 110GG. The green pixel group 110GG includes 16 pixels in which green pixels 110G are arranged four by four in a horizontal direction and a vertical direction in plan view.

As depicted in FIG. 8C, one on-chip lens 25 is arranged for every 16 pixels in which the pixels are arranged four by four in the horizontal direction and the vertical direction in plan view. For example, one on-chip lens 25 is arranged in one green pixel group 110GG.

A pixel separation section 33 includes a same-color pixel separation section 331 for separating adjacent pixels 110 of the same color and a different-color pixel separation section 332 for separating adjacent pixels 110 of different colors. Furthermore, the pixel separation section 33 is provided with an intersection 333 between the same-color pixel separation section 331 extending in the horizontal direction (column direction) and the same-color pixel separation section 331 extending in the vertical direction (row direction).

At least one of silicon oxide, titanium oxide, air, or a transparent electrode is embedded in the intersection 333 so as to extend in a thickness direction of a semiconductor layer 22. An amorphous silicon film containing boron with a high light absorption rate is embedded in the same-color pixel separation section 331 and the different-color pixel separation section 332 so as to extend in the thickness direction of the semiconductor layer 22.

### Effects by Second Variation of Third Embodiment

As described above, according to the second variation of the third embodiment, the effects similar to those of the first embodiment described above can be obtained, and since four green pixels 110G are arranged in the horizontal direction (column direction) and the vertical direction (row direction), it is possible to obtain phase difference detection information in both the horizontal direction and the vertical direction.

Note that, in the second variation of the third embodiment, a fixed charge film that generates a negative fixed charge may be formed on an inner wall surface of the intersection 333, or a p-type region may be formed on a side wall of the intersection 333.

### Fourth Embodiment

FIG. 9 is a plan view depicting an arrangement example of an on-chip lens 25 with respect to a pixel layout of a photodetection device 1E according to a fourth embodiment of the present disclosure. In FIG. 9, the same portions as those in FIG. 5 described above are denoted by the same reference signs, and detailed description thereof is omitted.

As depicted in FIG. 9, the photodetection device 1E includes, for example, a green pixel group 110GG. The green pixel group 110GG includes four pixels in which green pixels 110G are arranged two by two in a horizontal direction and a vertical direction in plan view.

A pixel separation section 41 includes a same-color pixel separation section 411 for separating adjacent pixels 110 of the same color and a different-color pixel separation section 412 for separating adjacent pixels 110 of different colors. Furthermore, the pixel separation section 41 includes a light condensing section 413 of light by the on-chip lens 25.

The light condensing section 413 has a bilaterally and vertically symmetrical rectangular shape in which at least one of silicon oxide, titanium oxide, air, or a transparent electrode is embedded so as to extend in a thickness direction of the semiconductor layer 22. An amorphous silicon film containing boron with a high light absorption rate is embedded in the same-color pixel separation section 411 and the different-color pixel separation section 412 so as to extend in the thickness direction of the semiconductor layer 22.

### Effects by Fourth Embodiment

As described above, according to the fourth embodiment, the similar effects as those of the first embodiment described above can be obtained, and a trench including the light condensing section 413 is stably formed, so that a silicon thickness can be further increased to secure a saturation charge amount. Note that, in the fourth embodiment, a fixed charge film that generates a negative fixed charge may be formed on an inner wall surface of the light condensing section 413, or a p-type region may be formed on a side wall of the light condensing section 413. Furthermore, the shape of the intersection 274 in the second embodiment may be a rectangular shape.

### Fifth Embodiment

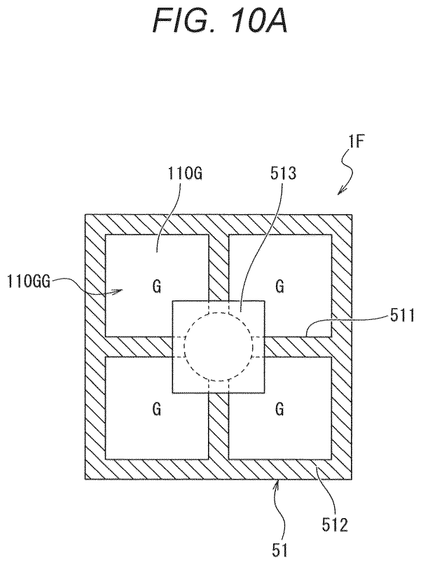

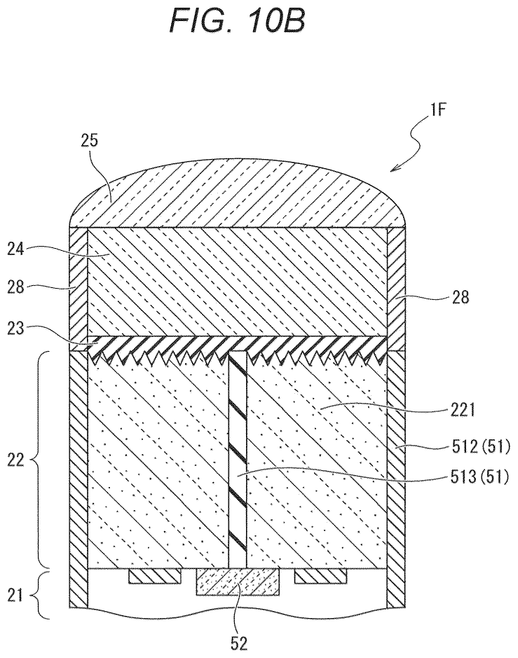

FIG. 10A is a plan view depicting a configuration example of a pixel layout of a photodetection device 1F according to a fifth embodiment of the present disclosure. In FIG. 10A, the same portions as those in FIG. 5 described above are denoted by the same reference signs, and detailed description thereof is omitted. FIG. 10B is a partial longitudinal cross-sectional view depicting an example of a semiconductor structure of the photodetection device 1F.

As depicted in FIG. 10A, the photodetection device 1F includes, for example, a green pixel group 110GG. The green pixel group 110GG includes four pixels in which green pixels 110G are arranged two by two in a horizontal direction and a vertical direction in plan view.

A pixel separation section 51 includes a same-color pixel separation section 511 for separating adjacent pixels 110 of the same color and a different-color pixel separation section 512 for separating adjacent pixels 110 of different colors. Furthermore, the pixel separation section 51 includes a light condensing section 513 of light by the on-chip lens 25.

The light condensing section 513 has a circular shape in which at least one of silicon oxide, titanium oxide, air, or a transparent electrode is embedded so as to extend in a thickness direction of the semiconductor layer 22. An amorphous silicon film containing boron with a high light absorption rate is embedded in the same-color pixel separation section 411 and the different-color pixel separation section 412 so as to extend in the thickness direction of the semiconductor layer 22.

As depicted in FIG. 10B, in the light condensing section 513, a shared pad section 52 is arranged on a side facing a wiring layer 21. The shared pad section 52 is used as a conductor and serves as a contact pad when a pixel transistor is formed on a different substrate.

### Effects by Fifth Embodiment

As described above, according to the fifth embodiment, effects similar to those of the first embodiment described above can be achieved. Furthermore, since the shared pad section 52 is arranged on the wiring layer 21 side of the light condensing section 513, the number of contact wires to the pixel transistor can be reduced, so that relaxation of a wiring design rule can be expected.

### Sixth Embodiment

A basic process of a method for manufacturing a photodetection device 1 will be described in a sixth embodiment of the present disclosure.

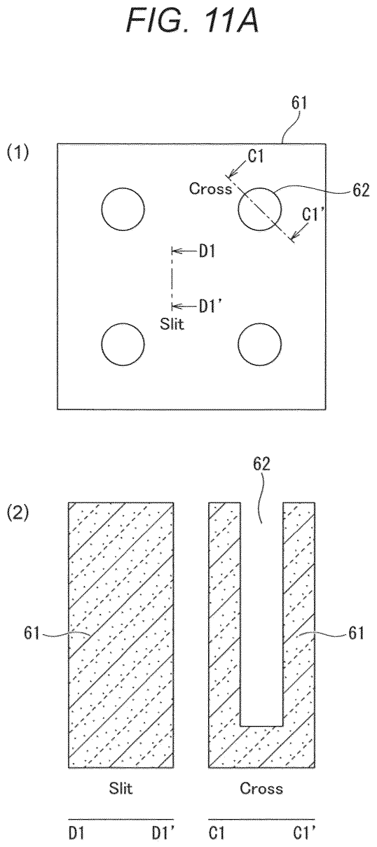

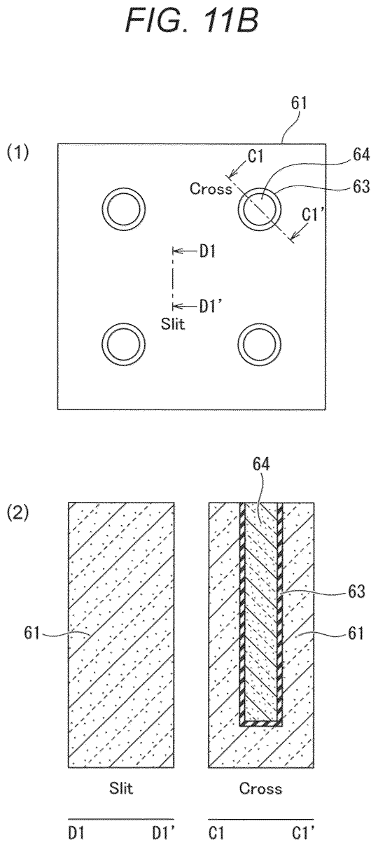

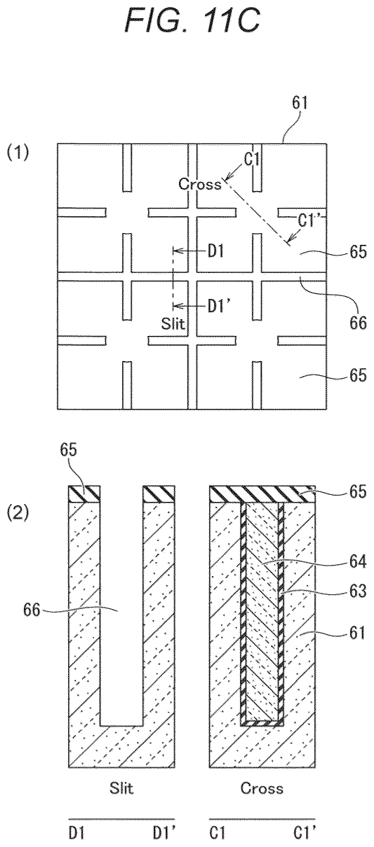

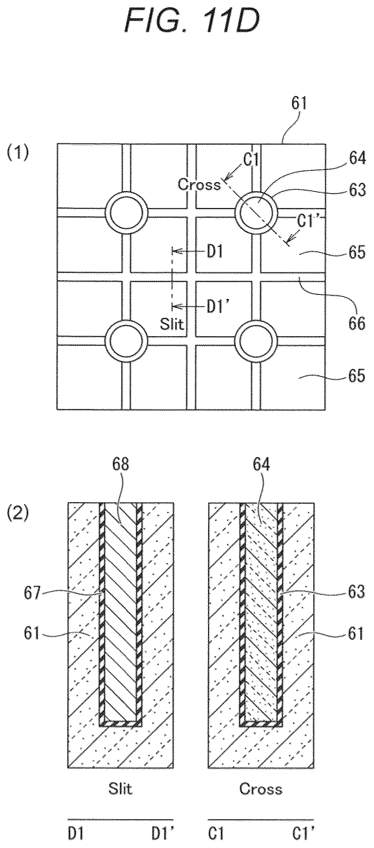

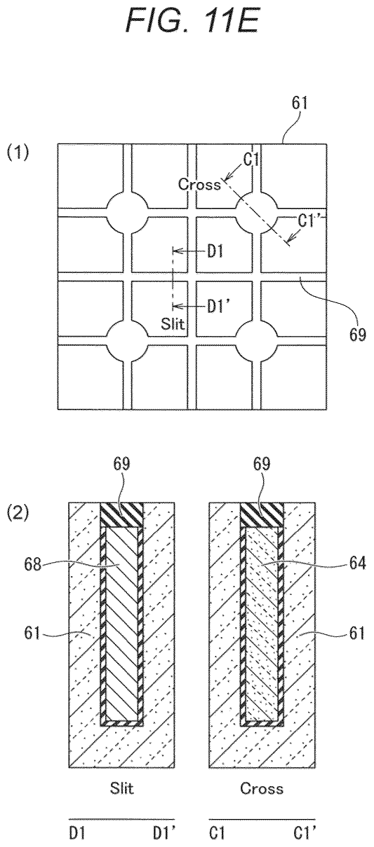

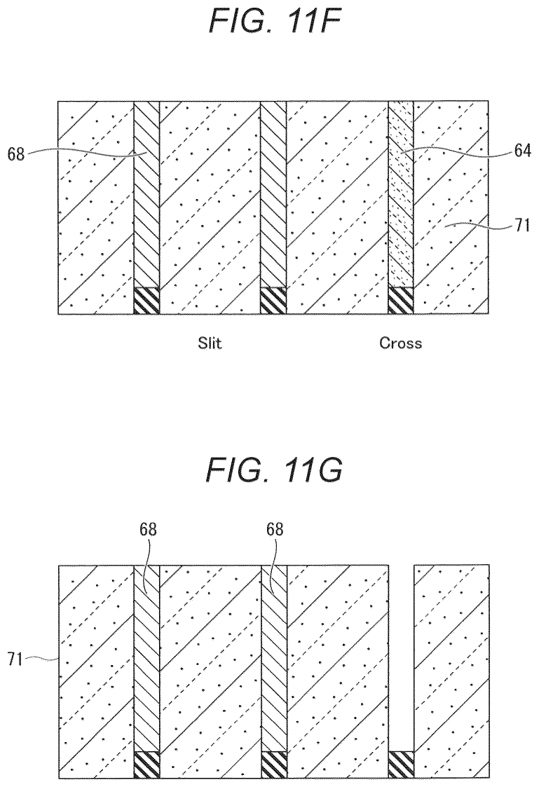

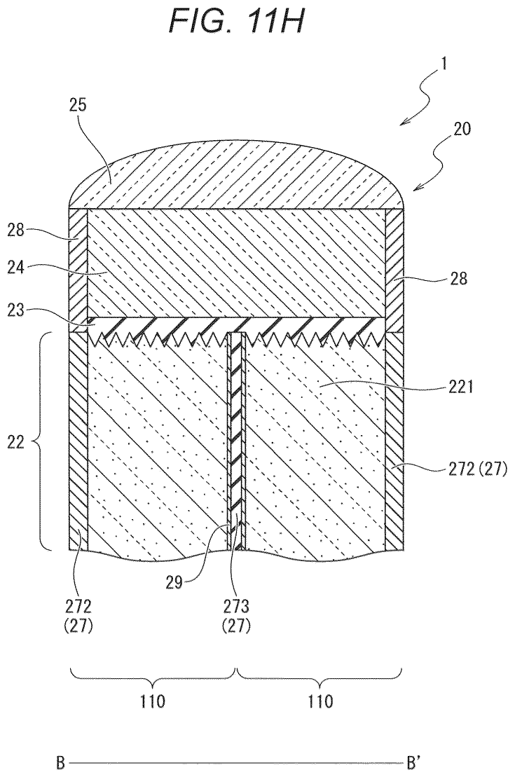

FIGS. 11A to 11H are cross-sectional views depicting a process procedure of the method for manufacturing the photodetection device 1 according to the sixth embodiment. Note that, FIGS. 11A(1) to 11E(1) are plan views as seen from a back surface side of the photodetection device 1, and FIGS. 11A(2) to 11E(2) are partial longitudinal cross-sectional views depicting an example of a semiconductor structure of the photodetection device 1 taken along lines C1-C1′ and D1-D1′. Line C1-C1′ is an imaginary line passing through a light condensing section 273 of a pixel separation section 27 in plan view. Line D1-D1′ is an imaginary line passing through a same-color pixel separation section 271 and a different-color pixel separation section 272 in plan view.

First, a silicon substrate 61 is prepared, and the light condensing section 273 on the silicon substrate 61 is opened by dry etching to form an opening 62 (FIG. 11A). After an insulating film 63 (silicon oxide, silicon nitride, and the like) is linearly embedded in the opening 62, polysilicon (Poly-Si) 64 is embedded and planarized by chemical mechanical polishing (CMP), etch back, and the like (FIG. 11B).

Next, a surface of the silicon substrate 61 is covered with a film 65 capable of obtaining a selection ratio between silicon such as silicon oxide and silicon nitride, and dry etching, and then the silicon substrate 61 is opened in a pixel separation shape to form an opening 66 (FIG. 11C). Then, an insulating film 67 and an amorphous silicon film 68 containing boron (hereinafter, referred to as an amorphous silicon film 68) are embedded in the opening 66 and planarized (FIG. 11D). Thereafter, the polysilicon 64 and the amorphous silicon film 68 are etched back and embedded with an insulating film 69 (FIG. 11E).

Then, after bonding to a logic substrate through a manufacturing process of a wiring layer and the like by a conventional manufacturing method, a CIS substrate 71 of the photodetection device 1 is subjected to silicon thinning (FIG. 11F). Then, when the polysilicon 64 and the amorphous silicon film 68 are subjected to alkali etching in a back surface process, since the amorphous silicon film 68 has a feature that the alkali etching does not proceed, wet etching proceeds only in the polysilicon 64 of the light condensing section 273 (FIG. 11G). Thereafter, a fixed charge film 29 and the like is embedded in the light condensing section 273 from which the polysilicon 64 is removed, and a semiconductor structure 20 of the photodetection device 1 is obtained (FIG. 11H).

### Seventh Embodiment

A basic process of a method for manufacturing a photodetection device 1 in a case where doping of p-type impurities is performed will be described in a seventh embodiment of the present disclosure.

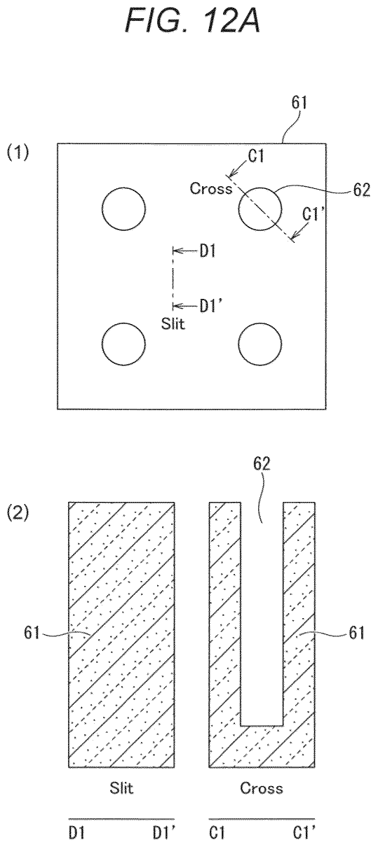

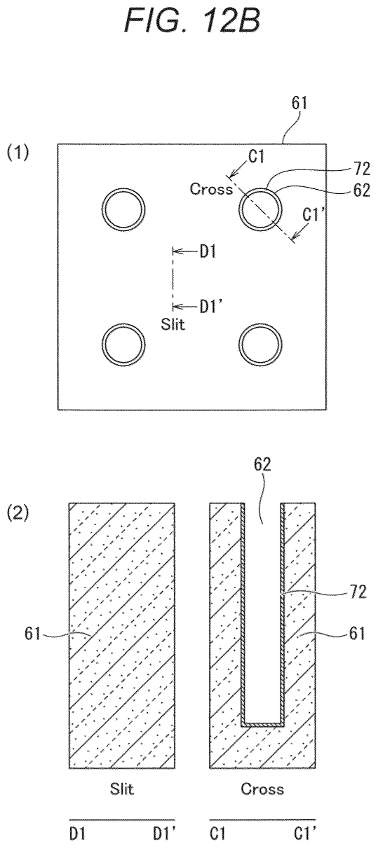

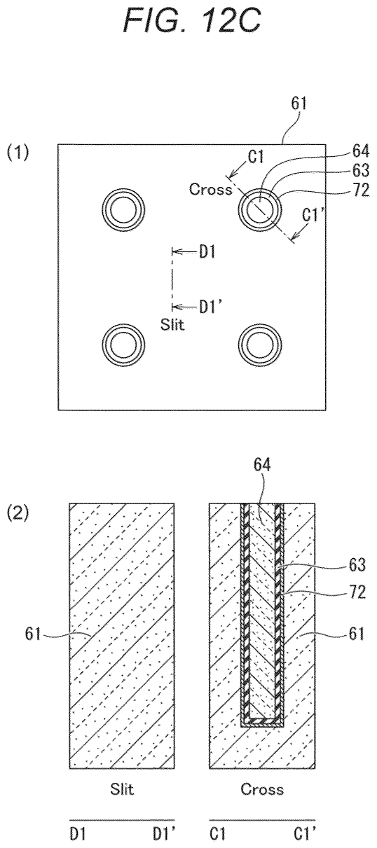

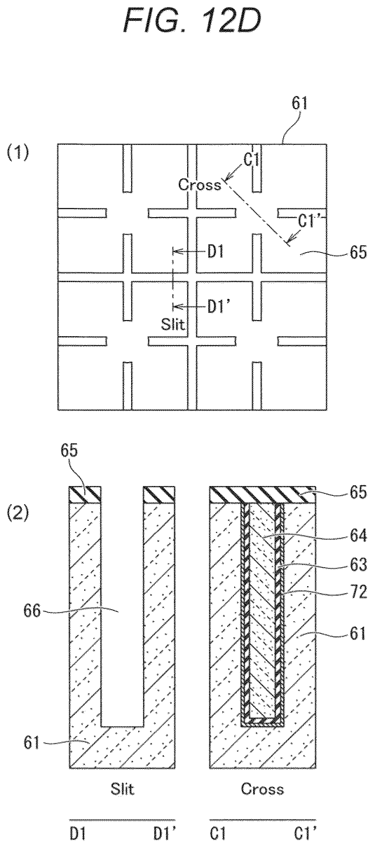

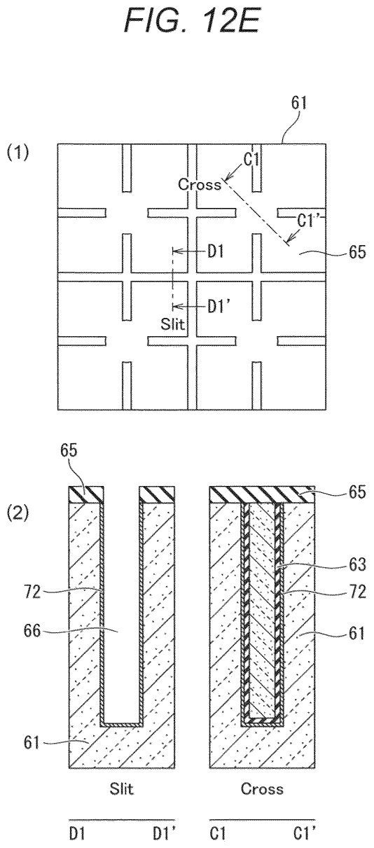

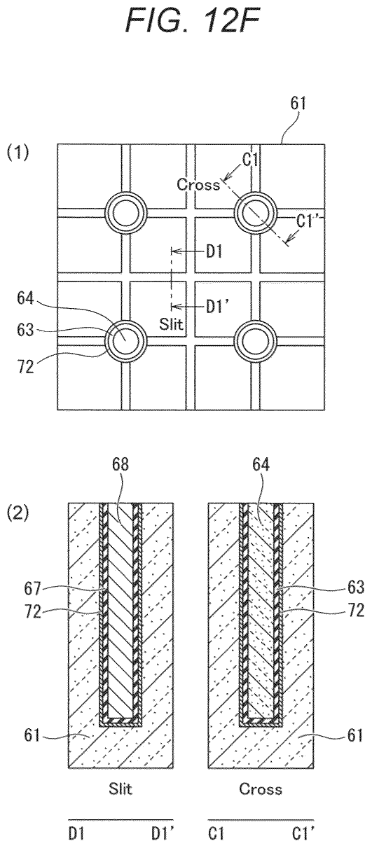

FIGS. 12A to 12H are cross-sectional views depicting a process procedure of the method for manufacturing the photodetection device 1 in a case where doping of p-type impurities is performed according to the seventh embodiment. Note that, FIGS. 12A(1) to 12F(1) are plan views as seen from a back surface side of the photodetection device 1, and FIGS. 12A(2) to 12F(2) are partial longitudinal cross-sectional views depicting an example of a semiconductor structure of the photodetection device 1 taken along lines C1-C1′ and D1-D1′. In FIG. 12A to 12H, the same portions as those in FIG. 11A to 11E described above are denoted by the same reference signs, and detailed description thereof is omitted.

First, a silicon substrate 61 is prepared, and the light condensing section 273 on the silicon substrate 61 is opened by dry etching to form an opening 62 (FIG. 12A). Solid-phase diffusion or plasma doping (PLAD) is performed on the opening 62 to form a p-type region 72 (FIG. 12B). Then, after an insulating film 63 (silicon oxide, silicon nitride, and the like) is linearly embedded in the opening 62 in which the p-type region 72 is formed, polysilicon 64 is embedded and planarized by CMP, etch back, and the like (FIG. 12C).

Next, a surface of the silicon substrate 61 is covered with a film 65 capable of obtaining a selection ratio between silicon such as silicon oxide and silicon nitride, and dry etching, and then the silicon substrate 61 is opened in a pixel separation shape to form an opening 66 (FIG. 12D). Then, solid-phase diffusion or plasma doping (PLAD) is performed on the opening 66 to form a p-type region 72 (FIG. 12E). Then, an insulating film 67 and an amorphous silicon film 68 are embedded in the opening 66 in which the p-type region 72 is formed and planarized (FIG. 12F). Thereafter, a manufacturing process similar to that in FIGS. 11E to 11G described above is executed.

### Eighth Embodiment

In an eighth embodiment of the present disclosure, a process in a case of forming a shallow trench (STI) will be described.

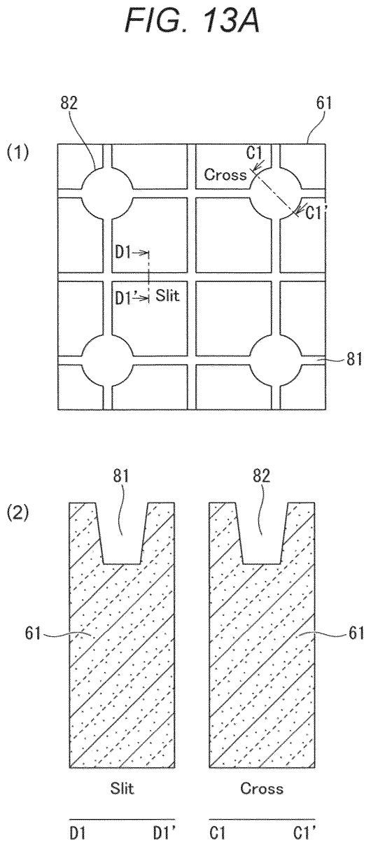

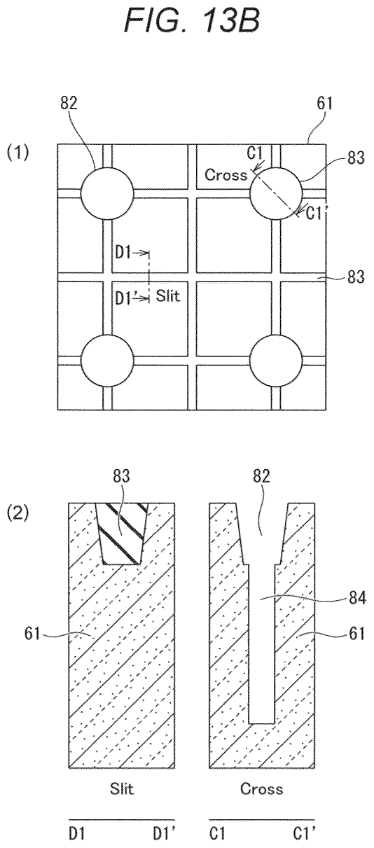

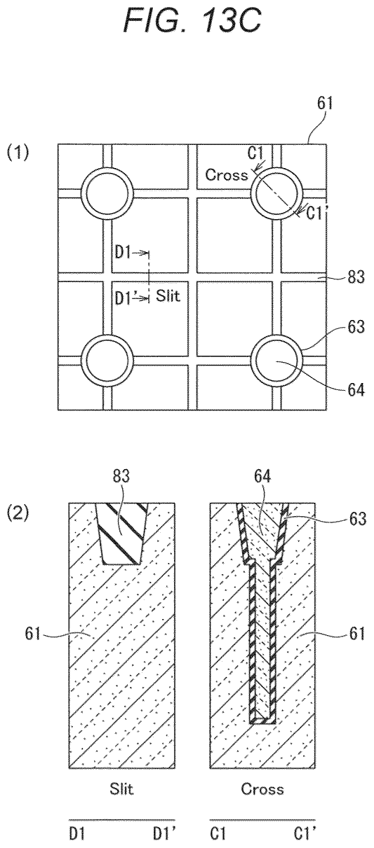

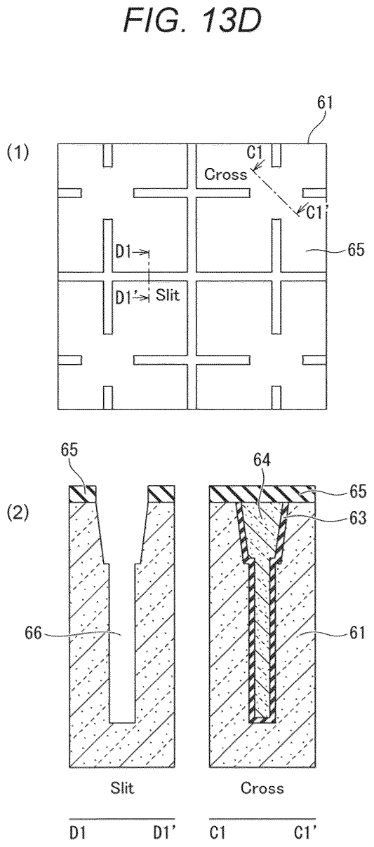

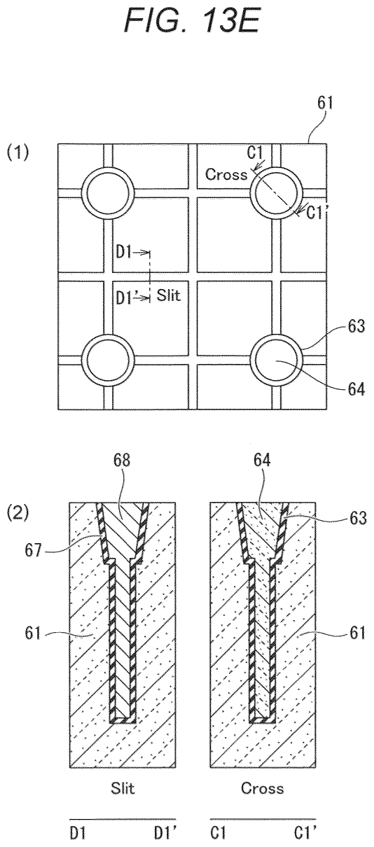

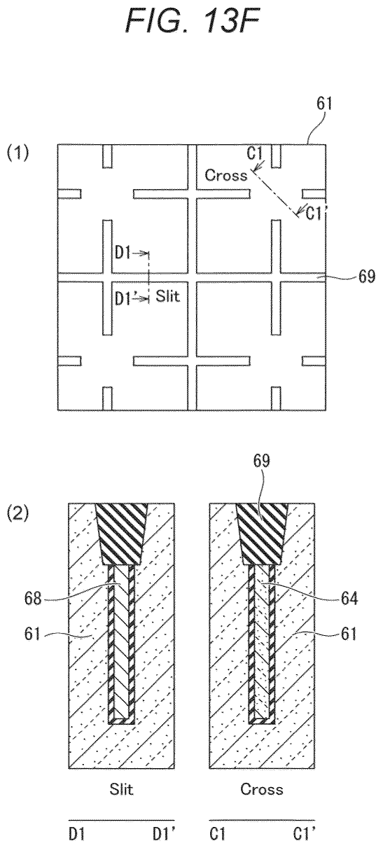

FIGS. 13A to 13F are cross-sectional views depicting a process procedure in a case where the STI is formed according to the eighth embodiment. Note that, FIGS. 13A(1) to 13F(1) are plan views as seen from a back surface side of the photodetection device 1, and FIGS. 13A(2) to 13F(2) are partial longitudinal cross-sectional views depicting an example of a semiconductor structure of the photodetection device 1 taken along lines C1-C1′ and D1-D1′. In FIG. 13A to 13F, the same portions as those in FIG. 11A to 11E described above are denoted by the same reference signs, and detailed description thereof is omitted.

First, a silicon substrate 61 is prepared, and a same-color pixel separation section 271 and a different-color pixel separation section 272 on the silicon substrate 61 are dug by dry etching to form a dug section 81, and a light condensing section 273 is dug by dry etching to form a dug section 82 (FIG. 13A). Then, after a coating film 83 (silicon oxide, silicon nitride, and the like) is embedded in the dug section 81, the dug section 82 is opened to form an opening 84 (FIG. 13B).

Next, after an insulating film 63 (silicon oxide, silicon nitride, and the like) is linearly embedded in the opening 84, polysilicon (Poly-Si) 64 is embedded and planarized by CMP, etch back, and the like (FIG. 13C).

Next, a surface of the silicon substrate 61 is covered with a film 65 capable of obtaining a selection ratio between silicon such as silicon oxide and silicon nitride, and dry etching, and then the silicon substrate 61 is opened in a pixel separation shape to form an opening 66 (FIG. 13D). Then, an insulating film 67 and an amorphous silicon film 68 are embedded in the opening 66 and planarized (FIG. 13E). Thereafter, the polysilicon 64 and the amorphous silicon film 68 are etched back and embedded with an insulating film 69 (FIG. 13F). Thereafter, a manufacturing process similar to that in FIGS. 11E to 11G described above is executed.

### Ninth Embodiment

In a ninth embodiment of the present disclosure, a manufacturing process in a case where alkali etching is not performed in a back surface process will be described.

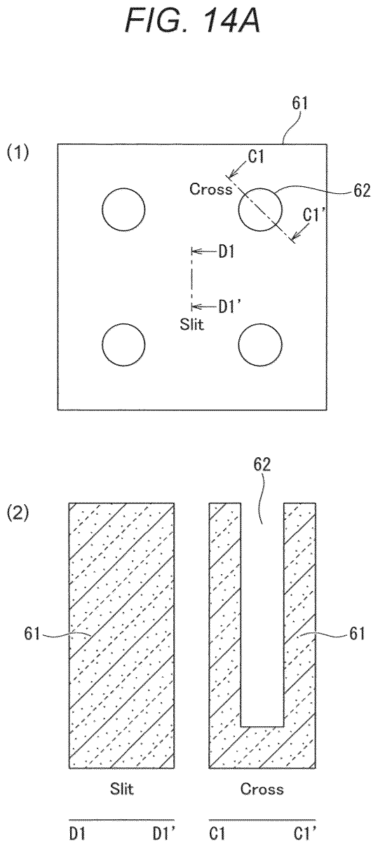

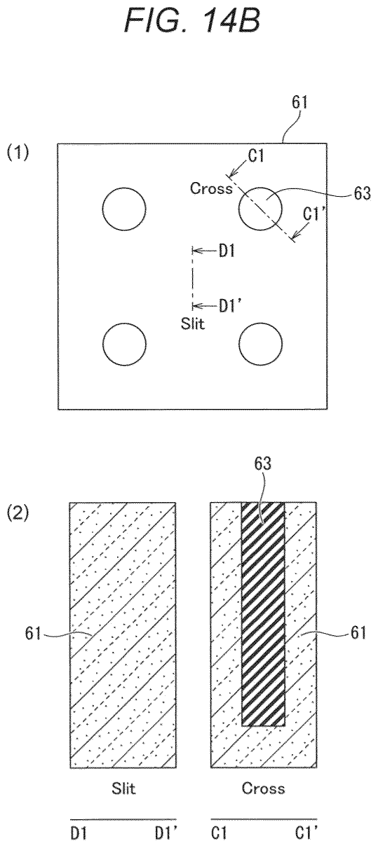

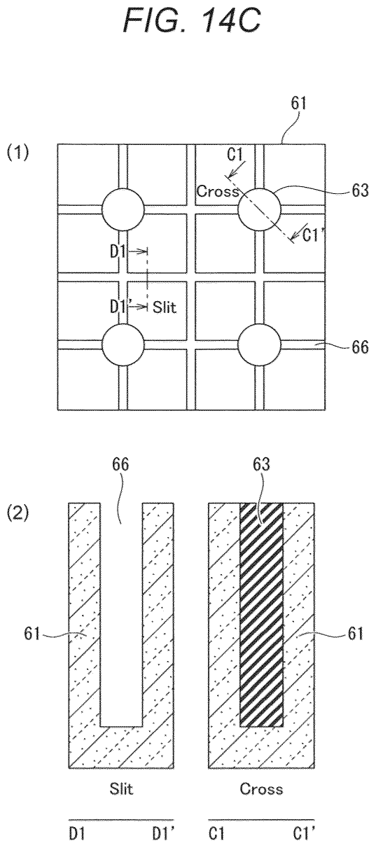

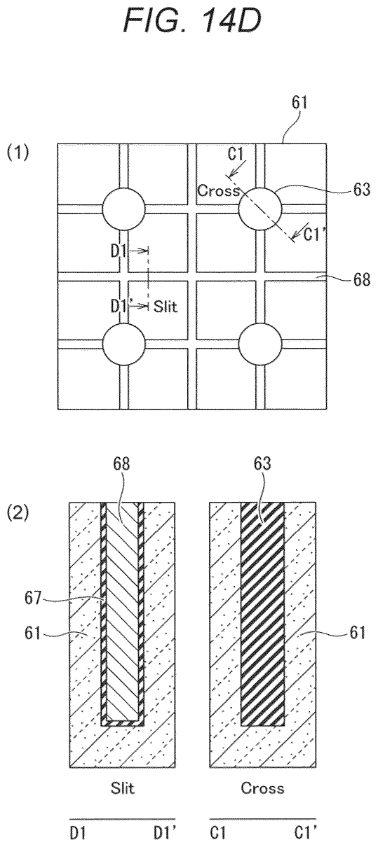

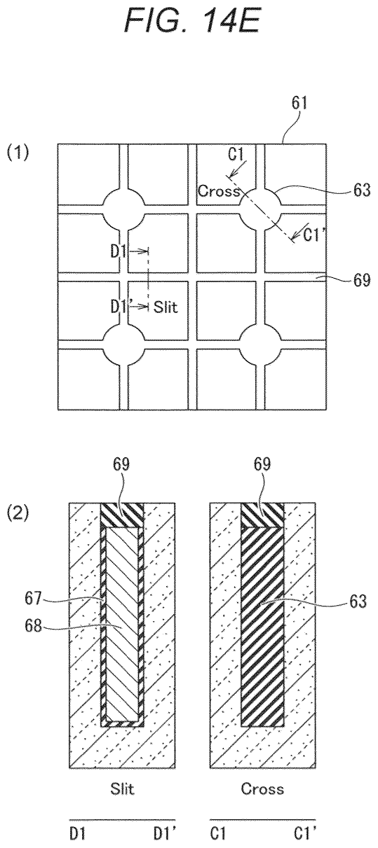

FIGS. 14A to 14E are cross-sectional views depicting a manufacturing process procedure in a case where the alkali etching is not performed in the back surface process in the ninth embodiment. Note that, FIGS. 14A(1) to 14E(1) are plan views as seen from a back surface side of the photodetection device 1, and FIGS. 14A(2) to 14E(2) are partial longitudinal cross-sectional views depicting an example of a semiconductor structure of the photodetection device 1 taken along lines C1-C1′ and D1-D1′. In FIG. 14A to 14E, the same portions as those in FIG. 11A to 11E described above are denoted by the same reference signs, and detailed description thereof is omitted.

First, a silicon substrate 61 is prepared, and the light condensing section 273 on the silicon substrate 61 is opened by dry etching to form an opening 62 (FIG. 14A). Next, an insulating film 63 (silicon oxide, silicon nitride, and the like) is embedded in the opening 62, and planarized by CMP, etch back, and the like (FIG. 14B).

Next, the silicon substrate 61 is opened in a pixel separation shape to form an opening 66 (FIG. 14C). Then, an insulating film 67 and an amorphous silicon film 68 are embedded in the opening 66 and planarized (FIG. 14D). Thereafter, the polysilicon 64 and the amorphous silicon film 68 are etched back and embedded with an insulating film 69 (FIG. 14E). Thereafter, a manufacturing process similar to that in FIGS. 11E to 11G described above is executed.

Therefore, only the light condensing section 273 is filled with non-silicon, and thus the concern of warpage is reduced.

### Other Embodiments

As described above, the present technology has been described by the first to ninth embodiments and the first and second variations of the third embodiment, but it should not be understood that the description and drawings forming a part of this disclosure limit the present technology. It will be apparent to those skilled in the art that various alternative embodiments, examples, and operation techniques can be included in the present technology when understanding the spirit of the technical content disclosed in the first to ninth embodiments described above. Furthermore, the configurations disclosed in the first to ninth embodiments and the first and second variations of the third embodiment can be appropriately combined within a range in which no contradiction occurs. For example, configurations disclosed in a plurality of different embodiments may be combined, or configurations disclosed in a plurality of different variations of the same embodiment may be combined.

### Application Example to Electronic Device

The photodetection device described above can be applied to various electronic devices such as, for example, an imaging device such as a digital still camera and a digital video camera, a mobile phone with an imaging function, or other devices having an imaging function.

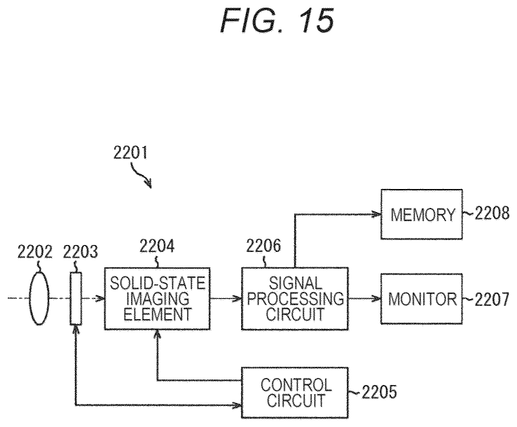

FIG. 15 is a block diagram depicting a configuration example of an imaging device as an electronic device to which the present technology is applied.

An imaging device 2201 depicted in FIG. 15 includes an optical system 2202, a shutter device 2203, a solid-state imaging element 2204 as a photodetection device, a control circuit 2205, a signal processing circuit 2206, a monitor 2207, and two memories 2208, and can image a still image and a moving image.

The optical system 2202 includes one or a plurality of lenses, and guides light from a subject (incident light) to the solid-state imaging element 2204 to form an image on a light receiving surface of the solid-state imaging element 2204.

The shutter device 2203 arranged between the optical system 2202 and the solid-state imaging element 2204 controls a light emission period to the solid-state imaging element 2204 and a light-shielding period according to control of the control circuit 2205.

The solid-state imaging element 2204 includes a package including the solid-state imaging element described above. The solid-state imaging element 2204 accumulates a signal charge for a certain period according to the light the image of which is formed on the light-receiving surface via the optical system 2202 and the shutter device 2203. The signal charges accumulated in the solid-state imaging element 2204 are transferred according to a drive signal (timing signal) supplied from the control circuit 2205.

The control circuit 2205 outputs the drive signal to control a transfer operation of the solid-state imaging element 2204 and a shutter operation of the shutter device 2203 to drive the solid-state imaging element 2204 and the shutter device 2203.

The signal processing circuit 2206 performs various kinds of signal processing on the signal charges output from the solid-state imaging element 2204. An image (image data) obtained by the signal processing circuit 2206 performing the signal processing is supplied to the monitor 2207 to be displayed or supplied to the memory 2208 to be stored (recorded).

Also in the imaging device 2201 configured as described above, the photodetection devices 1, 1A, 1B, 1C, 1D, 1E, and 1F can be applied in place of the solid-state imaging element 2204 described above.

### Application Example to Mobile Body

The technology according to an embodiment of the present disclosure (the present technology) can be applied to various products. For example, the technology according to an embodiment of the present disclosure may be implemented as a device to be mounted on a mobile body of any type, such as an automobile, an electric vehicle, a hybrid electric vehicle, a motorcycle, a bicycle, a personal mobility, an airplane, a drone, a vessel, or a robot.

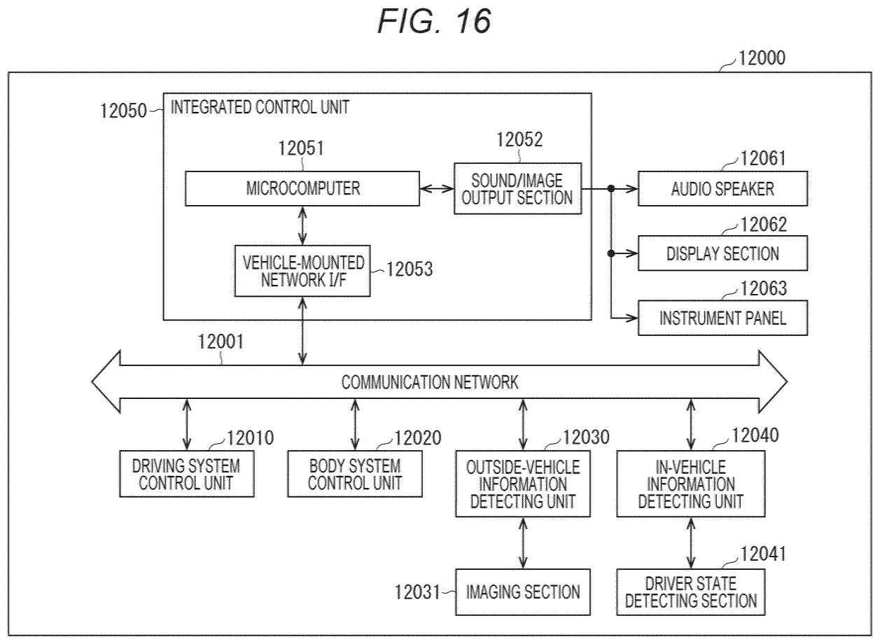

FIG. 16 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 16, the vehicle control system 12000 includes a driving system control unit 12010, a body system control unit 12020, an outside-vehicle information detecting unit 12030, an in-vehicle information detecting unit 12040, and an integrated control unit 12050. Furthermore, a microcomputer 12051, a sound/image output section 12052, and a vehicle-mounted network interface (I/F) 12053 are depicted as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

Furthermore, the microcomputer 12051 can output a control command to the body system control unit 12020 on the basis of the information outside the vehicle obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 16, an audio speaker 12061, a display section 12062, and an instrument panel 12063 are illustrated as the output device. The display section 12062 may, for example, include at least one of an on-board display and a head-up display.

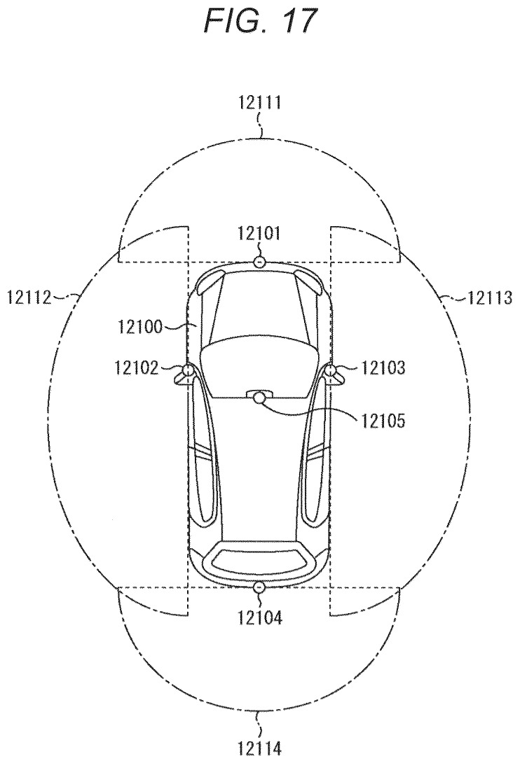

FIG. 17 is a diagram depicting an example of the installation position of the imaging section 12031.

In FIG. 17, a vehicle 12100 includes imaging sections 12101, 12102, 12103, 12104, and 12105 as the imaging sections 12031.

The imaging sections 12101, 12102, 12103, 12104, and 12105 are, for example, disposed at positions on a front nose, sideview mirrors, a rear bumper, and a back door of the vehicle 12100 as well as a position on an upper portion and the like of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The images of the front of the vehicle obtained by the imaging sections 12101 and 12105 are used mainly to detect a preceding vehicle, a pedestrian, an obstacle, a traffic signal, a traffic sign, a lane, or the like.

Note that, FIG. 17 depicts an example of imaging ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

Note that, the present disclosure can also have the following configurations.

(1)

A photodetection device including:
a semiconductor layer in which a plurality of pixels capable of generating an electric signal according to light incident from outside is arranged in a matrix;
a pixel separation region that is formed in the semiconductor layer and separates adjacent pixels from each other; and
an on-chip lens that is arranged on a light incident surface side of the semiconductor layer, is formed for each pixel group including two or more pixels, and condenses the light from the outside to the pixel group, in which
the pixel separation region includes a light condensing section of the light by the on-chip lens, and
the light condensing section includes a first material extending in a thickness direction of the semiconductor layer, and sections other than the light condensing section have a second material extending in the thickness direction of the semiconductor layer, the material different from the first material.
   (2)

The photodetection device according to (1) described above, in which
the first material is at least one of silicon oxide, titanium oxide, air, or a transparent electrode, and
the second material is a conductor with a higher light absorption rate as compared with the first material.
   (3)

The photodetection device according to (1) described above, in which
a region including an impurity of a conductivity type opposite to the conductivity type of the semiconductor layer is formed on a side wall of the pixel separation region.
   (4)

The photodetection device according to (3) described above, in which
the region including the impurity of the opposite conductivity type is formed on a side wall of the light condensing section.
   (5)

The photodetection device according to (1) described above, in which
the light condensing section forms a fixed charge film that generates a negative fixed charge.
   (6)

The photodetection device according to (1) described above, in which
the first material is further provided at an intersection at which the pixel separation region extending in a row direction and the pixel separation region extending in a column direction intersect.
   (7)

The photodetection device according to (1) described above, in which
the light condensing section has a round shape or a rectangular shape in plan view.
   (8)

The photodetection device according to (6) described above, in which
the intersection has a round shape or a rectangular shape in plan view.
   (9)

The photodetection device according to (1) described above, further including:
a wiring layer stacked on a surface of the semiconductor layer, the surface opposite to the light incident surface, the wiring layer including a metal wiring pattern for applying a predetermined voltage to the plurality of pixels, in which
in the light condensing section, a shared pad section is arranged on a side facing the wiring layer.
   (10)

The photodetection device according to (1) described above, in which
the pixel group includes two pixels in one row and two columns with respect to the on-chip lens.
   (11)

The photodetection device according to (1) described above, in which
the pixel group includes four pixels in two rows and two columns with respect to the on-chip lens.
   (12)

The photodetection device according to (6) described above, in which
the pixel group includes nine or more pixels in three rows and three columns or more with respect to the on-chip lens.
   (13)

The photodetection device according to (2) described above, in which
the conductor is an amorphous silicon film containing boron.
   (14)

An electronic device including:
a photodetection device including:
a semiconductor layer in which a plurality of pixels capable of generating an electric signal according to light incident from outside is arranged in a matrix;
a pixel separation region that is formed in the semiconductor layer and separates adjacent pixels from each other; and
an on-chip lens that is arranged on a light incident surface side of the semiconductor layer, is formed for each pixel group including two or more pixels, and condenses the light from the outside to the pixel group, in which
the pixel separation region includes a light condensing section of the light by the on-chip lens, and
the light condensing section includes a first material extending in a thickness direction of the semiconductor layer, and sections other than the light condensing section have a second material extending in the thickness direction of the semiconductor layer, the material different from the first material.

### REFERENCE SIGNS LIST

1, 1A, 1B, 1C, 1D, 1E, 1F, B1 Photodetection device
11 Pixel array section
12 Vertical drive section
13 Column processing section
14 Horizontal drive section
15 System control section
16 Signal processing section
17 Data storage section
18 Pixel drive line
19 Vertical signal line (VSL)
20 Semiconductor structure
21 Wiring layer
22 Semiconductor layer
23 Planarizing film
24 Color filter
25 On-chip lens
27 Pixel separation section
28 Light shielding wall
29 Fixed charge film
31, 32, 33, 41, 51 Pixel separation section
52 Shared pad section
61 Silicon substrate
62, 66, 84 Opening
63, 67, 69 Insulating film
64 Polysilicon
65 Film
68 Amorphous silicon film
71 CIS substrate
72, 222 P-type region
81, 82 Dug section
83 Coating film
110 Pixel
110B Blue pixel
110BG Blue pixel group
110G Green pixel
110GG Green pixel group
110R Red pixel
110RG Red pixel group
221 Photoelectric conversion section
271, 311, 321, 331, 411, 511 Same-color pixel separation section
272, 312, 322, 323, 412, 512 Different-color pixel separation section
273, 313, 413, 513 Light condensing section
274, 274-1, 274-2, 274-3, 323, 333 Intersection
2201 Imaging device
2202 Optical system
2203 Shutter device
2204 Solid-state imaging element
2205 Control circuit
2206 Signal processing circuit
2207 Monitor
2208 Memory
12000 Vehicle control system
12001 Communication network
12010 Drive system control unit
12020 Body system control unit
12030 Outside-vehicle information detecting unit
12031 Imaging section
12040 In-vehicle information detecting unit
12041 Driver state detection section
12050 Integrated control unit
12051 Microcomputer
12052 Sound/image output section
12061 Audio speaker
12062 Display section
12063 Instrument panel
12100 Vehicle
12101 to 12105 Imaging section
12111 to 12114 Imaging range

What is claimed is:

1. A photodetection device, comprising:
a semiconductor layer in which a plurality of pixels capable of generating an electric signal according to light incident from outside is arranged in a matrix;
a pixel separation region that is formed in the semiconductor layer and separates adjacent pixels from each other; and
an on-chip lens that is arranged on a light incident surface side of the semiconductor layer, is formed for each pixel group including two or more pixels, and condenses the light from the outside to the pixel group, wherein
the pixel separation region includes a light condensing section of the light by the on-chip lens, and
the light condensing section includes a first material extending in a thickness direction of the semiconductor layer, and sections other than the light condensing section have a second material extending in the thickness direction of the semiconductor layer, the material different from the first material.

2. The photodetection device according to claim 1, wherein
the first material is at least one of silicon oxide, titanium oxide, air, or a transparent electrode, and
the second material is a conductor with a higher light absorption rate as compared with the first material.

3. The photodetection device according to claim 1, wherein
a region including an impurity of a conductivity type opposite to the conductivity type of the semiconductor layer is formed on a side wall of the pixel separation region.

4. The photodetection device according to claim 3, wherein
the region including the impurity of the opposite conductivity type is formed on a side wall of the light condensing section.

5. The photodetection device according to claim 1, wherein
the light condensing section forms a fixed charge film that generates a negative fixed charge.

6. The photodetection device according to claim 1, wherein
the first material is further provided at an intersection at which the pixel separation region extending in a row direction and the pixel separation region extending in a column direction intersect.

7. The photodetection device according to claim 1, wherein
the light condensing section has a round shape or a rectangular shape in plan view.

8. The photodetection device according to claim 6, wherein
the intersection has a round shape or a rectangular shape in plan view.

9. The photodetection device according to claim 1, further comprising:
a wiring layer stacked on a surface of the semiconductor layer, the surface opposite to the light incident surface, the wiring layer including a metal wiring pattern for applying a predetermined voltage to the plurality of pixels, wherein
in the light condensing section, a shared pad section is arranged on a side facing the wiring layer.

10. The photodetection device according to claim 1, wherein
the pixel group includes two pixels in one row and two columns with respect to the on-chip lens.

11. The photodetection device according to claim 1, wherein
the pixel group includes four pixels in two rows and two columns with respect to the on-chip lens.

12. The photodetection device according to claim 6, wherein
the pixel group includes nine or more pixels in three rows and three columns or more with respect to the on-chip lens.

13. The photodetection device according to claim 2, wherein
the conductor is an amorphous silicon film containing boron.

14. An electronic device, comprising:
a photodetection device including:
a semiconductor layer in which a plurality of pixels capable of generating an electric signal according to light incident from outside is arranged in a matrix;
a pixel separation region that is formed in the semiconductor layer and separates adjacent pixels from each other; and
an on-chip lens that is arranged on a light incident surface side of the semiconductor layer, is formed for each pixel group including two or more pixels, and condenses the light from the outside to the pixel group, wherein
the pixel separation region includes a light condensing section of the light by the on-chip lens, and
the light condensing section includes a first material extending in a thickness direction of the semiconductor layer, and sections other than the light condensing section have a second material extending in the thickness direction of the semiconductor layer, the material different from the first material.
